(19) United States
(12) Patent Application Publication
(10) Pub. No.: US 2006/0280868 A1
(43) Pub. Date: Dec. 14, 2006

(54) Method for treating vapor deposition apparatus, method for depositing thin film, vapor deposition apparatus and computer program product for achieving thereof

(75) Inventors: Yoshitake Kato, Kanagawa (JP); Teruo Iwata, Tokyo (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/452,247

(22) Filed: Jun. 14, 2006

(30) Foreign Application Priority Data
Jun. 14, 2005 (JP) 2005-173247

(51) Int. Cl. C23C 16/00; G06F 19/00; B05C 11/00

(52) U.S. Cl. 427/248.1; 118/715; 118/696; 118/697; 700/117

(57) ABSTRACT

A method for treating a vapor deposition apparatus, a method for depositing a thin film, a vapor deposition apparatus and a computer program product are disclosed for providing a reduced cleaning frequency. Accumulated material is deposited on an interior wall of a chamber of a vapor deposition unit during deposition of a thin film. While the deposition of the thin film is repeated, a gas is emitted from the accumulated material to deteriorate an uniformity in the film thickness of the thin film. The method involves depositing an amorphous film to cover the accumulated material before any influence of the accumulated material deposited on the interior wall of the chamber on the thickness of the thin film is evident. Gas emission from the accumulated material can be prevented by covering the accumulated material with the amorphous film. This configuration provides a thin film having an improved uniformity of thickness.

This application is based on Japanese patent application No. 2005-173,247, the content of which is incorporated hereinto by reference.

### BACKGROUND

1. Field of The Invention

The present invention relates to a method for treating a vapor deposition apparatus, a method for depositing a thin film, a vapor deposition apparatus and a computer program product for achieving thereof.

2. Related Art

In recent years, it is expected that a high quality thin film having an uniform film thickness is deposited by employing a vapor deposition apparatus. During the deposition process, a source material for the thin film is adhered onto an interior wall of the chamber in the vapor deposition apparatus to form an accumulated material. While the deposition processes are repeatedly conducted in the chamber, the uniformity in the thickness of the deposited thin film is begun to be adversely affected by such accumulated material, thereby deteriorating the uniformity in the thickness of the deposited thin film. Therefore, a process for stripping the accumulated material that has been deposited on an interior wall of a chamber via a cleaning process is employed to prevent from a degradation of uniformity in the film thickness (see, for example, Japanese Patent Laid-Open No. H05-315,297 (1993)). Exemplary processes for cleaning may include a gas cleaning process. However, when a deposition of a thin film of a high dielectric material containing HfO₂, ZrO₂ or the like is conducted, it is difficult to gas-clean HfO₂, ZrO₂ or the like that have been adhered onto an interior wall of the chamber to remove thereof. Therefore, when a deposition of a thin film of a high dielectric material containing HfO₂, ZrO₂ or the like is conducted, it is necessary to wet-clean the interior wall of the chamber with a liquid chemical solution.

### SUMMARY OF THE INVENTION

Since the chamber should be opened for conducting the cleaning process so that the interior of the chamber is exposed to an atmosphere when the process for wet-cleaning the interior wall of the chamber with a liquid chemical solution is adopted, the temperature of the interior of the chamber should be considerably reduced. In addition, since the chamber is opened for conducting the wet cleaning process, the level of vacuum created in the chamber must be confirmed after finishing the cleaning process, requiring complicated procedures until a deposition of a thin film is started. Further, since it is required to elevate the temperature in the chamber to higher temperature after completing the cleaning process and before starting next deposition of a thin film, much time is additionally required for starting next deposition of a thin film, causing another problem.

Since the cleaning process requires much time and the post-cleaning processes also require much time and complicated procedures as described above, it is expected to reduce a frequency of carrying out the cleaning process. It is considered that a morphologic nature of the accumulated material, which adversely affects an uniformity in the thickness of the deposited thin film to deteriorate the uniformity in the film thickness, is polycrystalline. It is considered that the accumulated material that has been adhered onto the interior wall of the chamber may be morphologically changed while the deposition of the film on the substrate is repeated in the chamber, so that the size of the crystal grain is increased or a columnar crystal structure is formed in the process of the crystallization thereof, leading to providing a polycrystalline material. Therefore, the surface condition of the accumulated material becomes to be rough. Roughness of the surface of such accumulated material is increased as the crystallization thereof is progressed to provide a considerably increased surface area. Consequently, the present inventors have considered that such polycrystalline accumulated material easily adsorb gaseous source material for depositing the thin film and emits the adsorbed gas, so that the uniformity in the thickness of the thin film is deteriorated in the deposition process for the thin film. The present invention is made on the basis of such scientific knowledge and considerations.

According to one aspect of the present invention, there is provided a method of treating a vapor deposition apparatus after conducting a deposition of a thin film of a material a substrate in a chamber of the vapor deposition apparatus, comprising depositing a film of an amorphous material to cover the accumulated material that is deposited onto an interior wall of the chamber in the deposition of the thin film.

In such novel method, a film of an amorphous material is deposited, and the deposited amorphous film covers the accumulated materials that have been deposited on the interior wall of the chamber, so that an emission of a gas from the accumulated material and an adsorption of the emitted gas to the accumulated material during the deposition process can be prevented. This configuration provides obtaining a thin film having higher uniformity in the film thickness. In the conventional technology, the accumulated material adversely affects the uniformity in film thickness of the deposited thin film, and therefore it is required to clean the vapor deposition apparatus whenever the uniformity in the film thickness of thin the film is deteriorated. On the contrary, since the present invention involves depositing an amorphous film at the time an influence of the accumulated material upon the thickness of thin film deposited on the interior wall of the chamber has begun to be appeared (or just before the influence has begun to be appeared), deposition of the thin film having an improved uniformity can be maintained. Accordingly, the frequency of conducting the cleaning process can be considerably reduced. In addition to above, all portion of the amorphous film is not necessarily amorphous, and the amorphous film may be partially crystallized unless the influence upon the uniformity in thickness of the thin film deposited after the treatment is negligible.

In addition, the present invention is not limited to the treatment method, and may also be configured of an apparatus or a computer program product, which can provide advantageous effects that are similar to the advantageous effects described above.

According another aspect of the present invention, there is provided a vapor deposition apparatus for depositing a thin film on a substrate, comprising a chamber capable of being supplied with a vaporized source material of the thin film to deposit the thin film on the substrate; a temperature control unit for controlling a temperature in the chamber; a storage unit that is capable of storing a relationship between a number of the deposition cycles of the thin film and an uniformity in the film thickness of the deposited thin film; a counting unit for counting the number of the deposition cycles of the thin film in the chamber; and a determining unit for comparing the number of the deposition cycles counted by the counting unit with a predetermined number of deposition cycles to determine whether the number of the deposition cycles of the thin film counted by the counting unit is not larger than the predetermined number of the deposition cycles, predetermined number being obtained from the relationship between the number of the deposition cycles of the thin film and the uniformity in the thickness of the thin film, and the relationship being stored in the storage unit, wherein, if the determining unit determines that the number of the deposition cycles is larger than the predetermined number of the deposition cycles, the temperature control unit provides a control of the temperature in the chamber, and an amorphous film is deposited to cover the accumulated material that is adhered onto the interior wall of the chamber.

According further aspect of the present invention, there is provided a computer program product embodied on a computer that is capable of controlling a treatment process in a chamber of a vapor deposition apparatus, comprising: acquiring a relationship between a number of the deposition cycles of a thin film and an uniformity in the film thickness of the deposited thin film; acquiring a number of the deposition cycles of the thin film conducted in the chamber; comparing the acquired number of the deposition cycles of said thin film with a predetermined number of deposition cycles to determine whether said acquired number of the deposition cycles of the thin film is not larger than said predetermined number of the deposition cycles, said predetermined number of deposition cycles being obtained from the relationship between the number of the deposition cycles said thin film and the uniformity in the film thickness of the deposited thin film; and outputting a control signal for controlling a temperature in the chamber to a temperature control unit that is capable of conducting a temperature control in the chamber for depositing an amorphous film that covers an accumulated material adhered onto the interior wall of the chamber, if it is determined that the acquired number of the deposition cycles of the thin film is larger than said predetermined number of the deposition cycles.

### BRIEF DESCRIPTION OF THE DRAWINGS

The above and other objects, advantages and features of the present invention will be more apparent from the following description taken in conjunction with the accompanying drawings, in which:

FIG. 1 is a diagram, schematically illustrating a vapor deposition unit according to an embodiment of the present invention;

FIG. 2 is a flow chart, showing a deposition process;

FIG. 3 is a diagram, schematically illustrating a vapor deposition unit;

FIG. 4 is a graph, showing experimental results in reference example;

FIG. 5 is a graph, showing experimental results in example 1; and

FIG. 6 is a graph, showing experimental results in example 2.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments according to the present invention will be described as follows in further detail, in reference to the annexed figures. In all figures, identical numeral is assigned to an element commonly appeared in the figures, and the detailed description thereof will not be presented.

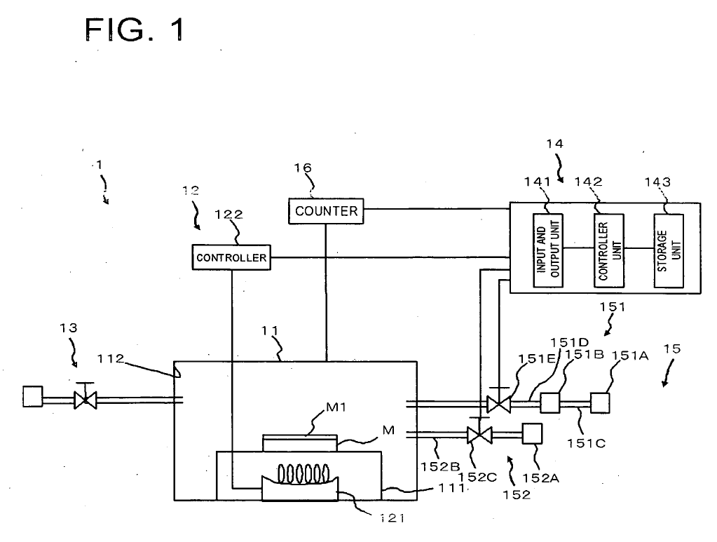

FIG. 1 is a schematic diagram of a vapor deposition apparatus 1 according to the present embodiment. The vapor deposition apparatus 1 is designed to deposit a thin film M1 on a substrate M via an atomic layer deposition (ALD) process.

The vapor deposition apparatus 1 includes a chamber 11, a heating unit 12, an exhausting unit 13, and a gas supply unit 15, which compose a deposition processing unit, and a control device 14.

A table 111 for supporting the substrate M during the deposition of the thin film M1 is mounted in an interior of the chamber 11.

The heating unit 12 includes a heater 121 disposed in the table 111 and a controller 122 for controlling a supply of an electric power to the heater 121. The heater 121 functions as heating the substrate M supported on the table 111. A temperature in the interior of the chamber 11 is increased via radiant heat, when the substrate M is heated by the heater 121. The controller 122 functions as controlling the supply of the electric power to the heater 121, and since the temperature in the chamber 11 is changed by the heater 121 as described above, the controller 122 for the heater 121 functions as a temperature control unit for controlling the temperature in the chamber 11. In addition to above, a sensor for detecting the temperature in the chamber 11 (not shown) is provided in the chamber 11.

The gas supply unit 15 includes a source gas supply unit 151 for supplying a source material of the thin film M1 into the interior of the chamber 11, and a purge gas supply unit 152 for supplying a purge gas into the interior of the chamber 11. The source gas supply unit 151 includes a source material container 151A, a vaporizer 151B connected to the source material container 151A, a duct 151C for connecting the source material container 151A to the vaporizer 151B, and a duct 151D for connecting the vaporizer 151B to the chamber 11. The source material container 151A is maintained at a room temperature, and the source material of the thin film M1 is stored in a liquid condition.

In such case, the thin film M1 may be, for example, a film employed as a capacitive film of a capacitor element or a gate insulating film of a metal oxide semiconductor field effect transistor (MOSFET). Typical thin film M1 may be so-called high-k film. Typical high-k film may include, for example, ZrOₓ, HfOₓ, HfAlOₓ, Al₂O₃, In₂O₃, Ga₂O₃, hafnium silicate (HfSiOₓ), zirconium silicate (ZrSiOₓ) or the like. In addition, typical high-k film may also include, for example, barium titanate (BaSrTiO₃), titanium oxide (TiO₂), tantalum oxide (Ta₂O₅), silicon nitride (Si₃N₄), silicon oxynitride (SiON), or alumina (Al₂O₃), PZT (lead zirconate titanate, (Pb, Zr) TiO₃), BST (barium strontium titanate, (Ba, Sr) TiO₃) or the like.

Such source material in the source material container 151A is vaporized in the vaporizer 151B, and the vaporized source material is supplied into the chamber 11 through the duct 151D. A solenoid valve 151E is provided in the duct 151D.

The purge gas supply unit 152 includes a cylinder 152A for storing the purge gas and a duct 152B for providing a connection between the cylinder 152A and the chamber 11. A solenoid valve 152C is also provided in the duct 152B. In addition to above, the purge gas supplied from the purge gas supply unit 152 and the source gas supplied from the source gas supply unit 151 flow through the interior of the chamber 11 parallel to the surface of the substrate M.

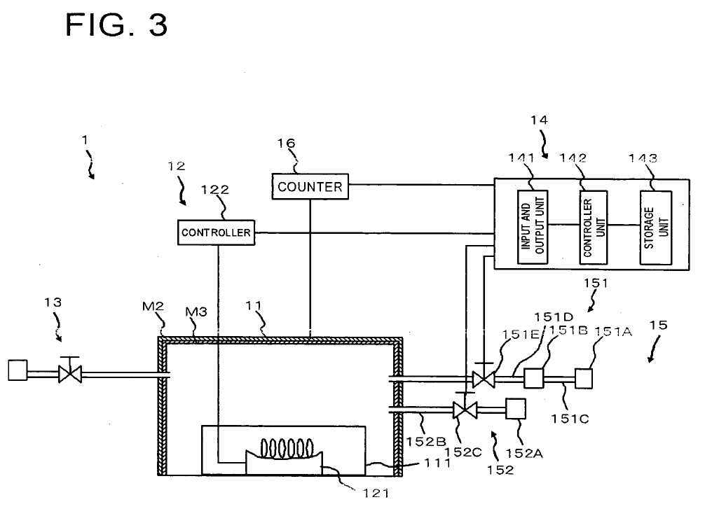

The control device 14 is a microcomputer, and functions as conducting an operation control of the controller 122 and an operation control of the gas supply unit 15. The control device 14 includes an input and output unit 141 for conducting an input and output of a signal, a controller unit 142 and a storage unit (storage device) 143. A controlling program for operating the controller unit 142 is stored in the storage unit 143. In addition, the storage unit 143 stores a relationship of an uniformity in the film thickness of the deposited thin film M1 with a frequency of conducting a deposition of the thin film M1 in the chamber 11, or more specifically, a critical number of the deposition cycles of the thin film M1 to cause a deterioration of the uniformity in the film thickness of the deposited thin film M1 that is beyond a predetermined uniformity (hereinafter referred to as a critical number of deposition cycles of the thin film M1). Since it is considered that the morphologic status of an accumulated material M2 that has been deposited in the chamber 11 (see FIG. 3) is changed to be polycrystalline by repeating the deposition cycles of the thin film M1 and such morphologic change adversely affects the film thickness of the deposited thin film M1, the uniformity in the film thickness of the thin film M1 is deteriorated when the number of the deposition cycles of the thin film M1 is beyond the critical number of deposition cycles.

Further, the storage unit 143 also stores time of supplying the source gas and the purge gas, which are essential information for conducting the deposition process of the amorphous film M3 (see FIG. 3) in the chamber 11. In addition, the storage unit 143 also stores a temperature in the chamber 11 during the deposition of the thin film M1 and a temperature in the chamber 11 during the deposition of the amorphous film M3. Further, the storage unit 143 also stores a highest number of the deposition cycle of the amorphous film M3 in the chamber 11 without a need for conducting a cleaning process. In the vapor deposition unit 1 of the present embodiment, the accumulated material M2, which has been adhered onto the interior wall 112 of the chamber 11 during the deposition of the material M1, is covered with the amorphous film M3, as discussed later in detail. The cycle of growing the accumulated material M2 on the interior wall of the chamber during the deposition of the material M1 on the substrate and coating the accumulated material M2 with the amorphous film M3, which is conducted without disposing a substrate within the chamber, are repeated. When a multiple-layered member composed of the accumulated material M2 and the amorphous film M3 is grown to have a predetermined thickness or larger, the multiple-layered member is highly possible to be flaked off from the interior wall 112 of the chamber 11. Therefore, when the multiple-layered member composed of the accumulated material M2 and the amorphous film M3 is grown to have a predetermined thickness or larger, or in other words, when the number of the deposition cycles of the amorphous film M3 is equal to or larger than a predetermined number, the inside of the chamber 11 must be cleaned.

Accordingly, the storage unit 143 previously stores the highest number of the deposition cycles of the amorphous film M3 without a need for conducting the cleaning process (hereinafter referred to as highest number of deposition cycle of the amorphous film M3 without a need for conducting the cleaning process).

The controller unit 142 functions as controlling the operation of the controller 122 and controlling the opening and shutting of the solenoid valves 151E and 152C in the gas supply unit 15. More specifically, the controller unit 142 functions as a determining unit, which compares a numeric value from a counter (counting unit) 16 that is capable of detecting the number of the deposition cycles of the thin film M1 carried out in the chamber 11 with the critical number of deposition cycles of the thin film M1 previously stored in the storage unit 143, and determines whether the number of the deposition cycles acquired from the counter 16 is beyond the critical number of the deposition cycles of the thin film M1. When the number of the deposition cycles counted by the counter 16 is larger than the critical number of the deposition cycles of the thin film M1, the controller unit 142 generates a control signal for decreasing the temperature in the chamber 11, and transmits such control signal to the controller 122. Then, the temperature in the chamber 11 is reduced as compared with that in the deposition process.

In addition, the controller unit 142 also functions as another determining unit, which compares the time for supplying the gas stored in the storage 143 that is essential for depositing the amorphous film M3, and the time for actually supplying the gas from the gas supply unit 15 during the deposition of the amorphous film M3 and then determines. When the controller unit 142 determines the actual time for supplying the gas is larger than the time for supplying the gas stored in the storage 143 that is essential for depositing the amorphous film M3, then the controller unit 142 generates a control signal for shutting the solenoid valves 151E and 152C and a control signal for elevating the temperature in the chamber 11, and the generated signals are transmitted to the solenoid valves 151E and 152C in the gas supply unit 15 and the controller 122, respectively. These procedures provide shutting the solenoid valves 151E and 152C to stop the supply of the gas from the gas supply unit 15 into the chamber 11, and the temperature in the chamber 11 is increased to the deposition temperature during the deposition of the thin film M1. Further, the controller unit 142 compares the highest number of the deposition cycle of the amorphous film M3 stored in the storage unit 143 and the number of actually conducted deposition cycles of the amorphous film M3, and if the number of the deposition cycles of the amorphous film M3 is equal to or larger than the highest number of the deposition cycles of the amorphous film without the need for cleaning, a signal for stopping the operation of the vapor deposition unit 1 is transmitted to promote starting the cleaning process in the chamber 11.

The process for depositing the thin film M1 by employing the vapor deposition unit 1 described above will be described as follows. First of all, a relationship between the number of deposition cycles of the thin film M1 and the uniformity in the film thickness of the thin film M1, or more specifically, the critical number of deposition cycles of the thin film M1, is figured out in advance. Then, the critical number of deposition cycles of the thin film M1 is stored in the storage unit 143 of the control device 14. In addition, time for supplying the source gas and the purge gas, which is essential information for depositing the amorphous film M3 on the accumulated material M2 that has been accumulated on the interior wall 112 of the chamber 11, is figured out in advance. Further, the highest number of deposition cycles of the amorphous film M3 is also stored in the storage unit 143.

Then, the thin film M1 is deposited on the substrate M. Since the vapor deposition unit 1 is dedicated to conduct an atomic layer epitaxy process in the present embodiment, the supply of the source gas from the source gas supply unit 151 into the chamber 11 and the supply of the purge gas from the purge gas supply unit 152 into chamber 11 are alternately repeated. This process achieves depositing the thin film M1 on the substrate M. In addition to above, during the repeated depositions of the thin film M1, an accumulated material M2 from the source material of the thin film M1 is gradually accumulated on the interior wall 112 of the chamber 11 (see FIG. 3).

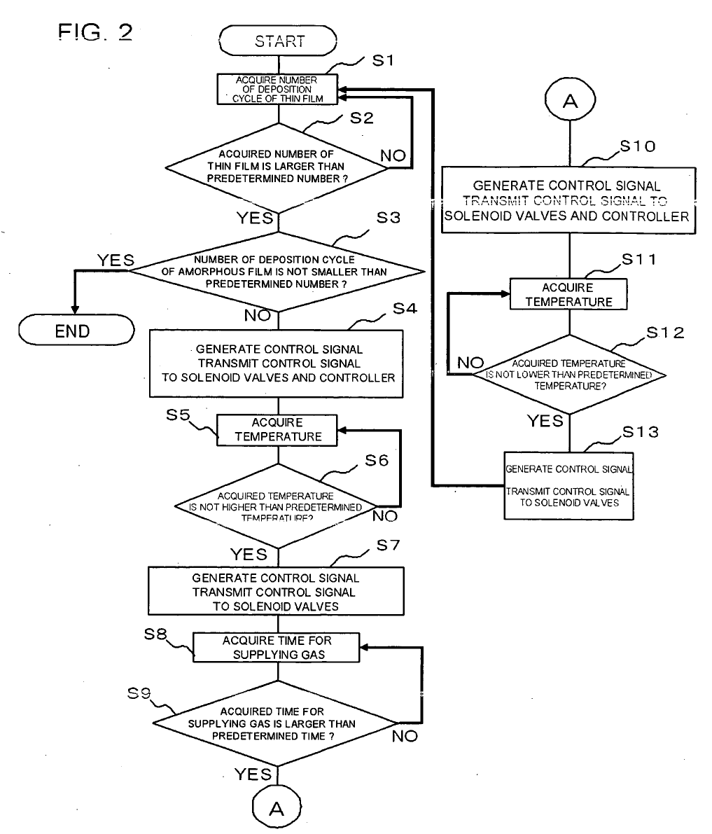

While the repeated implementations of loading the substrate M into chamber 11 and depositing the thin film M1 are continued, the controller unit 142 of the control device 14 acquires number of deposition cycles of the thin film M1 counted by the counter (counting unit) 16 as shown in FIG. 2 (step Si), and then compares the acquired number of deposition cycles of the thin film M1 with the critical number of deposition cycles of the thin film M1 stored in the storage unit 143, and eventually determines whether the number of deposition cycles of the thin film M1 counted by the counter 16 is larger than the critical number of deposition cycles of the thin film M1 (step S2).

If the controller unit 142 determines that the number of deposition cycles of the thin film M1 is not larger than the critical number of deposition cycles of the thin film M1 (step S2), the procedure returns to the acquisition of the number of deposition cycles of the thin film M1 again, and the comparison of the acquired number of deposition cycles of the thin film M1 with the critical number of deposition cycles of thin film M1 stored storage unit 143 is repeated. On the contrary, if the controller unit 142 determines that the number of deposition cycles of the thin film M1 was larger than the critical number of deposition cycles of the thin film M1, the controller unit 142 compares the number of actually-conducted deposition cycles of the amorphous film M3 with the highest number of deposition cycles of the amorphous film M3 stored in the storage unit 143. In addition to above, the number of actually-conducted deposition cycles of the amorphous film M3 can be counted by the above-described counter 16, and the controller unit 142 acquires the number of actually-conducted deposition cycles of the amorphous film M3 from the counter 16. When the number of deposition cycles of amorphous film M3 is equal to or higher than the highest number of deposition cycles without the need for cleaning, it is possible that the accumulated material M2 and amorphous film M3 may be faked off from the interior wall 112 of the chamber 11, such that the controller unit 142 transmits a signal for stopping the operation of the vapor deposition unit 1 to promote starting the cleaning process in the chamber 11 (step S3).

If the number of deposition cycles of the amorphous film M3 is less than the highest number of deposition cycles without the need for cleaning, the controller unit 142 generates a control signal for shutting the solenoid valves 151E and 152C of the gas supply unit 15. This control signal is transmitted to the solenoid valves 151E and 152C to shut the solenoid valves 151E and 152C. In addition, the controller unit 142 generates a control signal for reducing an electric power supplied to the heater 121, and then transmit the generated control signal to the controller 122 (step S4). The controller 122 receives the control signal, and then provides a reduced supply of electric power to the heater 121. This configuration provides decreasing the temperature in chamber 11, as compared with the temperature during the deposition.

In addition to above, when the inside of the chamber 11 is cooled to reduce the temperature therein, no substrate M is disposed in the chamber 11.

Next, the controller unit 142 of the control device 14 acquires the temperature detected by a sensor disposed in the chamber 11 (step S5), and determines whether the temperature in chamber 11 is reduced to reach a predetermined temperature (step S6). If the controller unit 142 determines that the temperature in the chamber 11 is reduced to reach the predetermined temperature, a control signal for opening valves is transmitted to the solenoid valves 151E and 152C in the gas supply unit 15 to sequentially open the solenoid valves 151E and 152C (step S7). This procedure provides supplying the source gas and the purge gas into the chamber 11.

Such supply of the source gas and the purge gas causes depositing the amorphous film M3 so as to cover the accumulated material M2 adhered on the interior wall 112 of the chamber 11 therewith, as shown in FIG. 3. Here, the thickness of the amorphous film M3 deposited on the chamber wall may be suitably selected so that the thin film M1 deposited on the substrate M after depositing the amorphous film M3 on the chamber wall is not adversely affected by the accumulated material M2. In addition, the temperature in the chamber 11 during the deposition of the amorphous film M3 may be preferably selected to a temperature, at which all portions of the deposited amorphous film M3 is in the amorphous state. The control device 14 acquires the time for supplying the source gas and the purge gas during deposition of the amorphous film M3 (step S8), and the controller unit 142 compares the acquired time for actually supplying the source gas and the purge gas with the time for supplying the source gas and the purge gas stored in the storage unit 143, which is the essential information for depositing the amorphous film M3 (step S9). If the controller unit 142 determines that the time for supplying the source gas and the purge gas is larger than the time for supplying stored in the storage unit 143, the controller unit 142 transmits a control signal for shutting the valves to the solenoid valves 151E and 152C, so that the solenoid valves 151E and 152C are shut to stop the supply of gases from the gas supply unit 15. In addition, a control signal for elevating the temperature in the chamber 11 to reach the temperature employed in the deposition process is transmitted from the controller unit 142 to the controller 122 to elevate the temperature in the chamber 11 to the temperature employed in the deposition process (step S10).

Next, the controller unit 142 acquires the temperature detected by the sensor in the chamber 11 (step 11), and if the controller unit 142 determines that the temperature in the chamber 11 is increased to the temperature employed in the deposition process (step S12), the controller unit 142 generates a control signal for opening the solenoid valves 151E and 152C. Then,.such control signal is transmitted from the controller unit 142 to the gas supply unit 15 (step S13) to sequentially open the solenoid valves 151E and 152C, so that the supply of the source gas from the source gas supply unit 151 and the supply of the purge gas from the purge gas supply unit 152 are re-started to conduct the deposition of the thin film M1.

In addition to above, when the temperature in the chamber 11 is increased to the temperature employed in the deposition process, the substrate M is loaded into chamber 11.

According to the present embodiment described above, the following advantageous effects can be achieved. In the present embodiment, the amorphous film M3 is deposited on the accumulated material M2 that has been deposited on the interior wall 112 of the chamber 11 to cover the accumulated material M2 with the amorphous film M3, so that an emission of a gas from the accumulated material M2 during the deposition process and an adsorption of the gas into the accumulated material M2 can be avoided. This configuration provides the thin film M1 having an improved uniformity in the film thickness. Since the vapor deposition unit 1 in the present embodiment is dedicated to be employed in the deposition of the thin film M1 via an atomic layer deposition process, the interior wall 112 of chamber 11 is very closer to the substrate M. Accordingly, nature of the thin film M1 deposited on the substrate M is easily influenced by the accumulated material M2 that has been adhered onto the interior wall 112 of the chamber 11, and therefore the non-uniform film thickness of the thin film M1 may be easily provided. However, the influence by the accumulated material M2 during the deposition of the thin film M1 can be surely prevented by covering the accumulated material M2 with the amorphous film M3, as in the present embodiment, thereby obtaining the thin film M1 having an improved uniformity in the film thickness.

In addition, while the accumulated material adversely affects the uniformity in the film thickness of the deposited thin film and thus it is necessary to conduct a cleaning of the vapor deposition unit once the uniformity in the film thickness of the deposited thin film is deteriorated in the conventional technology, the present embodiment involves depositing the amorphous film M3 shortly before the influence of the accumulated material M2 deposited on the interior wall 112 of the chamber 11 upon the thin film M1 is appeared, so that the thin film M1 having an improved uniformity in the film thickness can be deposited thereafter. This configuration provides considerably reducing the frequency for conducting the cleaning process for the vapor deposition unit 1. In addition to above, in the vapor deposition unit 1, when the number of deposition cycles of the amorphous film M3 is larger than the highest number of deposition cycles of the amorphous film M3 without the need for cleaning, or in other words, when the multiple-layered member composed of the accumulated material M2 and the amorphous film M3 is grown to have a thickness that is equal to or larger than a predetermined thickness by repeating the deposition of accumulated material M2 with chamber 11 and the deposition of the amorphous film M3 to cover the accumulated material M2 (it is considered that, in this multiple-layered member, portions of the amorphous film M3 located in the lower layer thereof is changed to be polycrystalline), it is possible that the multiple-layered member may be flaked off from the interior wall 112 of the chamber 11, and it is sufficient to conduct a cleaning process.

In addition, in the present embodiment, since the amorphous film M3, which covers the accumulated material M2, is relatively difficult to be flaked off, during the deposition process for the thin film M1 after the treatment of the vapor deposition unit 1, it is preventing the deposited thin film M1 from being contaminated with the flaked-off amorphous film M3.

Further, since the amorphous film M3 is deposited by employing the same source material as employed for depositing the thin film M1 in the present embodiment, a production cost required for depositing the amorphous film M3 can be reduced, as compared with depositing the amorphous film by employing other type of source material. Further, since the amorphous film M3 is deposited by employing the same source material as employed for depositing the thin film M1, the accumulated material M2 is composed of the same type of the material as employed in forming the amorphous film M3. Accordingly, the amorphous film M3 can be easily formed on the portions where the accumulated material M2 is adhered, and therefore it is ensured to cover the accumulated material M2 with the amorphous film M3.

In addition, in the present embodiment, the relationship between the number of deposition cycles of the thin film M1 and the uniformity in the film thickness of the thin film M1 is previously sorted out, and the vapor deposition unit 1 is configured that the deposition of the amorphous film M3 is started when the number of deposition cycles of the thin film M1 is larger than the critical number of deposition cycles, so that tasks of the operator can be reduced.

While the preferred embodiments of the present invention have been described-above in reference to the annexed figures, it should be understood that the disclosures above are presented for the purpose of illustrating the present invention, and various configurations other than the above described configurations can also be adopted. For example, while the apparatus for conducting the atomic layer epitaxy process is employed for the vapor deposition unit 1 in the above-described embodiment, the available apparatus is not limited thereto, and an apparatus for depositing a thin film via a chemical vapor deposition (CVD) process may alternatively be employed for the vapor deposition unit 1. Further, while the amorphous film M3 is deposited by employing the source material of the thin film M1 in the aforementioned embodiment, the available source material is not limited thereto, and other source material than that for the thin film M1 may also be employed to deposit an amorphous film. For example, a source material for forming the material of the interior wall 112 of the chamber 11 (quartz, aluminum, titanium or the like) may also be employed to deposit an amorphous film. In addition, while the vapor deposition unit 1, in which the source gas and the purge gas are supplied parallel to the surface of the substrate M, is employed in the aforementioned embodiment, the available the vapor deposition unit is not limited thereto, and, for example, a vapor deposition unit, in which the source gas and the purge gas are supplied to the surface of the substrate M from the vertical direction thereto, may be employed.

### EXAMPLES

### Reference Example

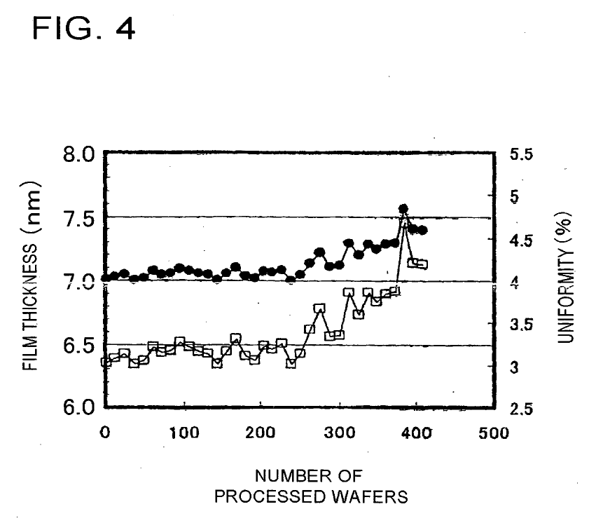

A gas containing hafnium tetrakis(diethylamide) (source gas) and O₂-based gas containing 10% of O₃ (purge gas) were employed to deposit a thin film of HfO₂ via an atomic layer epitaxy process. A vapor deposition unit, which is configured to flow the source gas and the purge gas parallel to the surface of the substrate M, was employed in this example. Deposition temperature was set to 300 degree C., and a thickness of a deposited thin film on a substrate was set to 70 angstroms (7 nm). Depositions of thin films on 1,000 pieces of substrates were sequentially conducted, and it was found that the uniformity in the thickness of the deposited film was deteriorated after depositing films on 300 pieces of substrates. Results are shown in FIG. 4. In FIG. 4, a black dot indicates film thickness, and a white square indicates uniformity in film thickness. In addition to above, equation for obtaining the uniformity in the film thickness was presented as:

(maximum film thickness in a thin film−minimum film thickness in the thin film)/(average film thickness of the thin film×2). Larger calculated value according to the above equation indicates lower uniformity.

### Example 1

In example 1, the vapor deposition unit employed in the reference example was also employed, and the source gas and the purge gas employed in reference example were employed to deposit a thin film via an atomic layer epitaxy process. If number of the processed substrates by depositing a thin film was reached to 300 pieces (i.e., critical number of processed substrates for commencing deterioration of the uniformity in the film thickness of the thin film in reference example, (critical number of deposition cycles of the thin film)), the temperature in the chamber was decreased to 200 degree C. Then, the source gas and the purge gas of predetermined volumes, which correspond to depositing 10 thin films, were introduced into the chamber at a temperature of 200 degree C. to deposit an amorphous film of HfO₂ on the accumulated material that had been adhered onto the interior wall of the chamber. Here, the temperature in the chamber was decreased, because at least a portion of an amorphous film of HfO₂ is crystallized at 300 degree C. Temperature in the chamber during the deposition process for the amorphous film of HfO₂ is preferably set at a temperature, at which all portions of the deposited film are substantially amorphous. When the deposition of the amorphous film was finished, the temperature in the chamber was increased to the deposition temperature, and then depositions of the thin films on 300 pieces of the substrates were conducted. These operations were repeated to process 1,000 pieces of substrates.

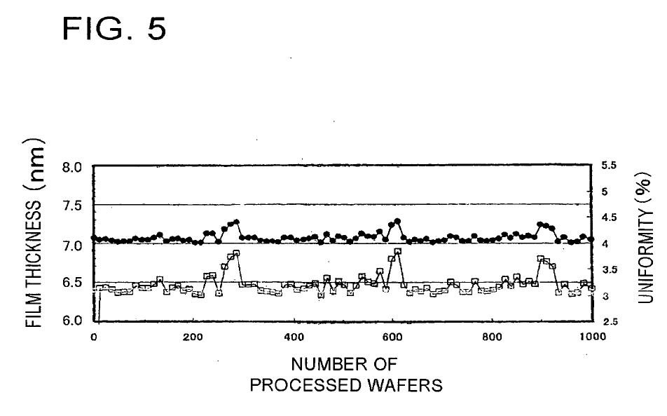

Results are shown in FIG. 5. Similarly as in FIG. 4, a black dot indicates film thickness, and a white square indicates uniformity in film thickness. In addition, equation for obtaining the uniformity in the film thickness is the same as in reference example. It was confirmed that the degradation of the uniformity in the film thickness of the thin film can be avoided by depositing the amorphous film onto the interior wall of the chamber. In addition, while it is necessary to clean the vapor deposition unit in processing every 300 pieces of substrates in case that the amorphous film is not deposited as described in reference example, the present example achieves depositing thin films on 1,000 pieces of substrates without conducting the cleaning process, and thus it is confirmed that the frequency for the cleaning process can e considerably reduced.

### Example 2

In example 2, a source gas containing zirconium tetrakis(diethylamide) was employed to deposit a thin film of ZrO₂ via an atomic layer epitaxy process. The employed vapor deposition unit and the type of the purge gas were same as employed in example 1. In addition, deposition temperature was set to 270 degree C., and a thickness of a deposited thin film on a substrate was set to 80 angstroms (8 nm). When the number of the processed substrates by depositing the thin film was reached to 300 pieces, the temperature in the chamber was reduced to 200 degree C. Then, the source gas and the purge gas of predetermined volumes, which correspond to depositing 10 thin films, were introduced into the chamber at a temperature of 200 degree C. to deposit an amorphous film of ZrO₂ on the accumulated material that had been adhered onto the interior wall of the chamber. When the deposition of the amorphous film was finished, the temperature in the chamber was increased to the deposition temperature, and then the 300 pieces of the substrates were processed to deposit thin films. These operations were repeated to process 2,000 pieces of substrates.

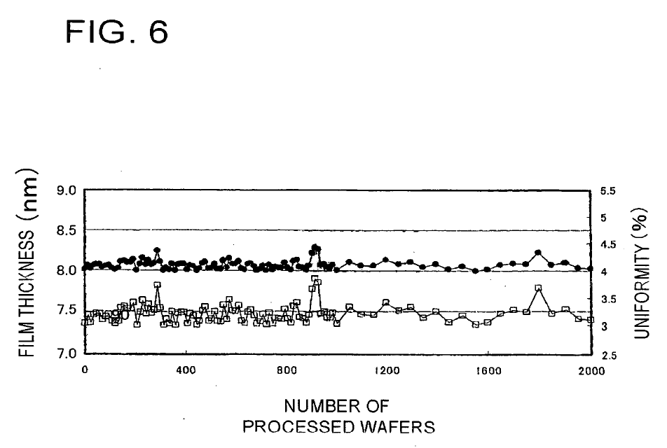

Results are shown in FIG. 6. Similarly as in FIG. 4, a black dot indicates film thickness, and a white square indicates uniformity in film thickness. In addition, equation for obtaining the uniformity in the film thickness is the same as in reference example. It was confirmed that the degradation of the uniformity in the film thickness of the thin film can be avoided by depositing the amorphous film onto the interior wall of the chamber. Further, the present example achieves depositing thin films on 2,000 pieces of substrates without conducting the cleaning process, and thus it is confirmed that the frequency for the cleaning process can e considerably reduced.

It is apparent that the present invention is not limited to the above embodiment, that may be modified and changed without departing from the scope and spirit of the invention.

1. A method for treating a vapor deposition apparatus after conducting a deposition of a thin film of a material-on a substrate in a chamber of a vapor deposition apparatus, comprising:
depositing a film of an amorphous material to cover an accumulated material that is deposited onto an interior wall of said chamber in said deposition of said thin film.

2. The method for treating a vapor deposition apparatus according to claim 1, wherein a source material of said amorphous film is a source material of said material of the thin film deposited on said substrate.

3. A method for depositing a thin film by employing a vapor deposition apparatus, comprising:
treating the vapor deposition apparatus via said method of treating the vapor deposition apparatus as set forth in claim 1; and
depositing the thin film on another substrate in the chamber of said vapor deposition apparatus, after treating said vapor deposition apparatus.

4. The method for depositing the thin film according to claim 3, wherein said thin film is deposited via an atomic layer deposition process in said depositing the thin film.

5. The method for depositing the thin film according to claim 3, further comprising:
figuring out a relationship between a number of deposition cycles of said thin film and an uniformity in the film thickness of said deposited thin film;
comparing a number of deposition cycles of said thin film on the substrate within said chamber with a predetermined number of deposition cycles to determine whether the number of the deposition cycles of said thin film on the substrate within said chamber is not larger than said predetermined number of the deposition cycles, said predetermined number being obtained from said relationship between the number of deposition cycles of said thin film and the uniformity in the film thickness of said deposited thin film;
treating said vapor deposition apparatus by depositing said amorphous film to cover said accumulated material that is adhered onto the interior wall of said chamber, by employing said method of treating the vapor deposition apparatus, if it is determined that the number of deposition cycles of said thin film on the substrate within said chamber is larger than the predetermined value; and
depositing the thin film on another substrate in said chamber of said vapor deposition apparatus, after treating said vapor deposition apparatus.

6. A vapor deposition apparatus for depositing a thin film on a substrate, comprising:
a chamber capable of being supplied with a vaporized source material of the thin film to deposit the thin film on said substrate;
a temperature control unit for controlling a temperature in said chamber;
a storage unit that is capable of storing a relationship between a number of the deposition cycles of said thin film and an uniformity in the film thickness of said deposited thin film;
a counting unit for counting the number of the deposition cycles of said thin film in said chamber; and
a determining unit for comparing the number of the deposition cycles counted by said counting unit with a predetermined number of deposition cycles to determine whether the number of the deposition cycles of said thin film counted by said counting unit is not larger than said predetermined number of the deposition cycles, predetermined number being obtained from said relationship between the number of the deposition cycles of said thin film and the uniformity in the thickness of the thin film, and said relationship being stored in said storage unit,
wherein, if said determining unit determines that the counted number of the deposition cycles is larger than the predetermined number of the deposition cycles, said temperature control unit provides a control of the temperature in said chamber, and an amorphous film is deposited to cover the accumulated material that is adhered onto the interior wall of said chamber.

7. A computer program product embodied on a computer that is capable of controlling a treatment process in a chamber of a vapor deposition apparatus, comprising:
acquiring a relationship between a number of the deposition cycles of a thin film and an uniformity in the film thickness of the deposited thin film;
acquiring a number of the deposition cycles of the thin film on a substrate conducted in said chamber;
comparing the acquired number of the deposition cycles of said thin film with a predetermined number of deposition cycles to determine whether said acquired number of the deposition cycles of the thin film is not larger than said predetermined number of the deposition cycles, said predetermined number of deposition cycles being obtained from the relationship between the number of the deposition cycles said thin film and the uniformity in the film thickness of the deposited thin film; and
outputting a control signal for controlling a temperature in said chamber to a temperature control unit that is capable of conducting a temperature control in said chamber for depositing an amorphous film that covers an accumulated material adhered onto the interior wall of said chamber, if it is determined that the acquired number of the deposition cycles of said thin film is larger than said predetermined number of the deposition cycles.
